(19) United States
(12) Patent Application Publication
(10) Pub. No.: US 2025/0384858 A1
(43) Pub. Date: Dec. 18, 2025

(54) METHOD AND APPARATUS FOR AUTOMATIC BAND SELECTION FOR DISPLAYPORT

(71) Applicant: Foundation for Research and Business, Seoul National University of Science and Technology, Seoul (KR)

(72) Inventors: Won Young Lee, Seoul (KR); Min Ji KIM, Seoul (KR)

(21) Appl. No.: 18/973,084

(22) Filed: Dec. 8, 2024

(30) Foreign Application Priority Data
Jun. 12, 2024 (KR) 10-2024-0076494

(51) Int. Cl. G09G 5/00; H03L 7/089; H04L 7/033

(52) U.S. Cl. CPC G09G 5/008; H03L 7/089; H04L 7/0331

(57) ABSTRACT

Provided are a method and an apparatus for automatic band selection for DisplayPort. The method may include: performing an operation on output signals of a bang-bang phase detector (BBPFD) by respective logic gates and outputting the output signal on which the operation has been performed; generating CUP, CDN, and HOLD signals according to a predefined condition by inputting the output signal to a latch; increasing or decreasing a bit count by inputting the generated CUP, CDN and HOLD signals to an up-down counter; and adjusting a band in correspondence with the increase or decrease in the bit count.

### CROSS-REFERENCES TO RELATED APPLICATIONS

This U.S. patent application claims priority to Korean patent application no. 10-2024-0076494 filed on Jun. 12, 2024, the entire content of which is hereby incorporated by reference.

### BACKGROUND OF THE INVENTION

### Field of the Invention

The present disclosure relates to a method and an apparatus for automatic band selection for DisplayPort, and more particularly, to a method and an apparatus for automatically selecting a band for DisplayPort by adopting a wideband clock and data recovery circuit for DisplayPort based on multiple bands.

### Background of the Related Art

DisplayPort needs to support a wide range of data rates. A most recent version of DisplayPort needs to support up to 20 Gb/s. In addition, up to 1.62 Gb/s, i.e., a lowest data rate in a previous version thereof also needs to be supported simultaneously. Therefore, to support such a wide range of data rates, a receiving terminal uses a clock data recovery (CDR) to recover data at different frequencies. The CDR is a circuit configured to generate a clock suitable for damaged data received through a channel and recover the damaged data using the generated clock. Therefore, to track a wide range of data rates, the CDR usually adopts an oscillator with multiple bands.

FIGS. 1A-1B shows graphs for comparing frequencies between a single-band oscillator and a multi-band oscillator.

FIG. 1A shows poor noise and jitter characteristics due to a great gain when a wide range of frequencies are implemented by the single-band oscillator. Accordingly, the multi-band oscillator as shown in FIG. 1B is mainly used to implement a wide range while maintaining noise and jitter characteristics. When an oscillator is implemented with multiple bands, a wide range may be supported while a small gain is maintained in each band. However, a multi-band oscillator needs to be capable of automatically setting a band in which a clock appropriate for a received data rate is located. To do so, a wide range digitally controlled oscillator (DCO) need to be equipped with an automatic band selecting (ABS) circuit configured to automatically set a band. Therefore, there is a need for an ABS circuit configured to automatically select a corresponding band according to the received data rate, among multiple bands.

Since a CDR for DisplayPort in the related art does not support up to 20 Gb/s, the CDR uses a single band in most cases. Even in a case of multiple bands, the CDR uses a manual selection method performed from outside, instead of an automatic selection method. In addition, in the related art used for CDRs with multiple bands other than those for DisplayPort, the CDRs may operate only in one of two ranges, i.e., a high speed and a low speed according to an operating principle, and thus, it may be difficult to achieve both a high speed of 20 Gb/s and a low speed of 1.62 Gb/s.

The background art is disclosed in Korean Patent Publication No. 10-0793988 (published on Jan. 16, 2008).

### SUMMARY OF THE INVENTION

Therefore, the present disclosure has been made in view of the above problems, and it is an object of the present disclosure to provide a method and apparatus for automatic band selection for DisplayPort by adopting a wideband clock and data recovery circuit for DisplayPort based on multiple bands.

In addition, it is also an object of the present disclosure to provide a method and an apparatus for automatically selecting a band for DisplayPort to ensure fast frequency tracking by employing a data rate detection method using a latch.

To accomplish the above object, according to one aspect of the present disclosure, there is provided an automatic band selection method performed by an apparatus for automatic band selection for DisplayPort, the apparatus having circuits including logic gates, a latch, an up-down counter and the automatic band selection method including: performing an operation on output signals of a bang-bang phase detector (BBPFD) by respective logic gates and outputting the output signal on which the operation has been performed; generating CUP, CDN, and HOLD signals according to a predefined condition by inputting the output signal to the latch; increasing or decreasing a bit count by inputting the generated CUP, CDN and HOLD signals to the up-down counter; and adjusting a band in correspondence with the increase or decrease in the bit count.

In addition, the performing of the operation and the outputting may include performing AND, XOR, and NOR logical operations using a Fast_norm signal used to generate an output and a Slow signal output in correspondence with a relationship between a clock and a data rate, among output signals of the bang-bang phase detector, and outputting signals obtained by performing the AND, XOR, and NOR logical operations, and the bang-bang phase detector outputs a signal by dividing a frequency-divided signal into four sections according to the data rate.

In addition, the generating of the CUP, CDN, and HOLD signals may include generating the CUP or CDN signal for increasing or decreasing the bit count when the Fast_norm signal is identical to the Slow signal, and generating the HOLD signal to maintain the bit count when the Fast_norm signal is different from the Slow signal, wherein the latch operates to be synchronized by an edge detector with a clock that operates with a period of 64 divisions.

In addition, the adjusting of the band may include adjusting of the band to be inversely proportional to the bit count.

In addition, according to another aspect of the present disclosure, there is provided an apparatus for automatic band selection for DisplayPort, the apparatus including: a signal output unit configured to output a signal obtained by performing, by a logic gate, an operation using a Fast_norm signal used to generate an output and a Slow signal output in correspondence with to a relationship between a clock and a data rate, among output signals of a bang-bang phase detector (BBPFD), a signal generation unit configured to generate CUP, CDN, and HOLD signals according to a predefined condition when the output signal is input to a latch; and a band adjustment unit configured to adjust a band in correspondence with an increase or decrease in a bit count when the bit count is increased or decreased according to input of the generated CUP, CDN, and HOLD signals to an up-down counter.

According to the present disclosure as described above, performance of a clock data recovery (CDR) circuit may be enhanced by introducing a multi-band oscillator and an automatic band selection function to support a wide data range. Thus, such effects that damaged data at various frequencies are quickly and accurately recovered and requirements for high data rates are stably satisfied may be obtained.

In addition, according to the present disclosure, a sophisticated clock and data recovery function with improved jitter performance may be provided to support next-generation standards for DisplayPort and other video interface technologies.

In addition, according to the present disclosure, high performance and reliability may be provided in a field in which fast data recovery and stable clock generation and high-speed data transmission are essentially needed, i.e., in such application fields as high-definition video and graphics transmission, medical imaging and telemedicine, virtual reality and augmented reality systems.

### BRIEF DESCRIPTION OF THE DRAWINGS

FIGS. 1A-1B show graphs for comparing frequencies between a single-band oscillator and a multi-band oscillator.

FIG. 2 is a circuit configuration diagram showing an apparatus for automatic band selection for DisplayPort according to an embodiment of the present disclosure.

FIG. 3 is an operational flowchart illustrating a method for automatic band selection for DisplayPort according to an embodiment of the present disclosure.

FIGS. 4A-4B show diagrams illustrating a process of generating a content delivery network (CDN) signal according to an embodiment of the present disclosure.

FIGS. 5A-5B show diagrams illustrating a process of generating a CUP signal according to an embodiment of the present disclosure.

FIGS. 6A-6B are diagrams illustrating a process of generating a HOLD signal according to an embodiment of the present disclosure.

FIG. 7 is a state diagram of a counter according to an embodiment of the present disclosure and a diagram illustrating an example of implementation of a HOLD logic.

FIGS. 8A-8C are graphs showing a simulation result to an embodiment of the present disclosure.

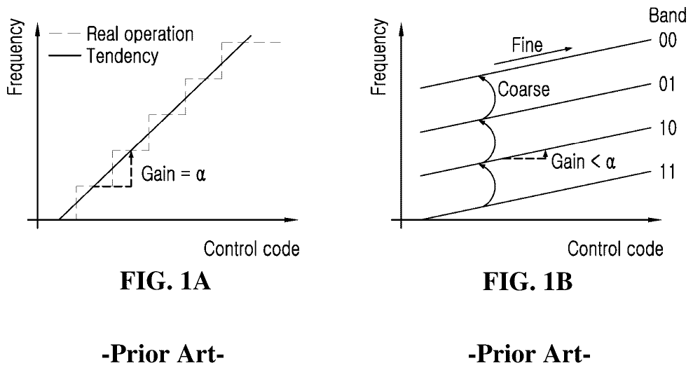

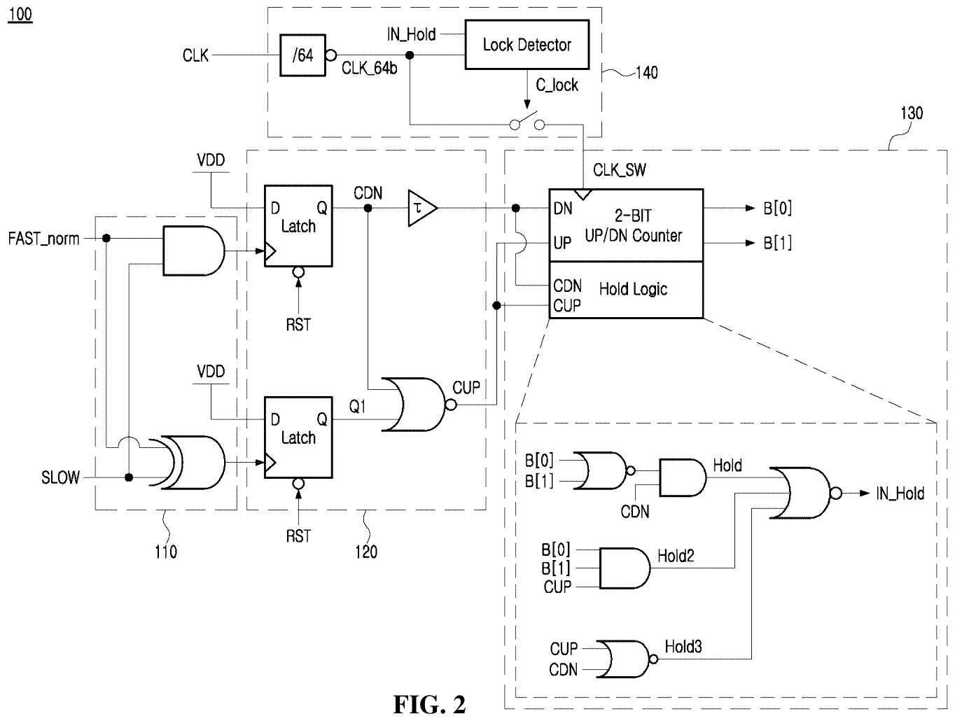

### DETAILED DESCRIPTION OF THE PREFERRED EMBODIMENT

Hereinafter, an embodiment will be described in detail with reference to the attached drawings. In this process, thicknesses of lines or sizes of components in the drawing may be exaggerated for clarity and convenience of description.

Additionally, terms used herein have been defined in consideration of functions provided in the present disclosure, and may vary according to an intention of a user or an operator, a precedent, or the like. Accordingly, it will be understood that the terms should be interpreted as having a meaning that is consistent with their meaning in the context of the specification.

Hereinafter, embodiments of the present disclosure will be described in detail with reference to the accompanying drawings.

Referring to FIG. 2, an apparatus for automatic band selection for DisplayPort according to an embodiment of the present disclosure. Is described.

FIG. 2 is a circuit configuration diagram showing the apparatus for automatic band selection for DisplayPort according to an embodiment of the present disclosure.

As shown in FIG. 2, an apparatus 100 for automatic band selection for DisplayPort according to an embodiment of the present disclosure includes a signal output unit 110, a signal generation unit 120, and a band adjustment unit 130.

The apparatus 100 for automatic band selection for DisplayPort according to an embodiment of the present disclosure is a circuit to which a single loop clock and data recovery (CDR) based on a phase lock poop (PLL) capable of controlling frequencies and phases may be applied, and is included in a frequency detector (FD) to be applied to a coarse stage of a multi-band oscillator, i.e., a stage for finding a band.

The signal output unit 110 outputs a signal obtained according to an operation performed by a logic gate using a Fast_norm signal used to generate an output and a Slow signal output in correspondence with a relationship between a clock and a data rate, among output signals of a bang-bang phase detector (BBPFD).

Here, the bang-bang phase detector generates a Fast signal and the Slow signal by combining the Fast_norm signal and a Fast_inv signal. In an embodiment of the present disclosure, the Fast_norm signal and the flow signal are used, among four output signals (the Fast_norm, Fast_inv, Fast, and Slow signals) of the bang-bang phase detector.

Therefore, a signal obtained by performing an AND, exclusive or (XOR), or NOR logical operation using the Fast_norm signal and the Slow signal may be output.

In addition, the signal generation unit 120 generates a CUP, CDN, or HOLD signal according to a predefined condition, as the signal output from the signal output unit 110 is input into a latch.

In detail, when the Fast_norm signal is identical to the Slow signal, the CUP or CDN signal is generated to increase or decrease a bit count, and when the Fast_norm signal is different from the Slow signal, a HOLD signal is generated to maintain the bit count.

In addition, when the CUP, CDN or HOLD signal generated from the signal generation unit 120 is input to an up-down counter, the bit count is increased or decreased, and the band adjustment unit 130 adjusts a band in correspondence with the increase or decrease in the bit count.

At this time, the band adjustment unit 130 adjusts the band to be inversely proportional to the bit count by lowering the band when the bit count is increased according to an input of the CUP signal to the up-down counter, and raising the band when the bit count is increased according to an input of the CDN signal to the up-down counter. In addition, when the HOLD signal is input, the band is maintained to a current state.

Finally, the clock generation unit 140 generates a clock with a period of 64 divisions, and a reset (RST) signal is input to the latch of the signal generation unit 120. At this time, an edge detector configured to generate an output in correspondence with a delay difference between an edge of a clock pulse and an edge of a delayed clock pulse is used as a circuit that generates a reset signal for the latch. When an input clock is received, the edge detector according to an embodiment of the present disclosure operates to reset at each edge at which the input clock is ended. Accordingly, the operation is performed regardless of a clock, but an edge is synchronized with the clock by the edge detector to be reset.

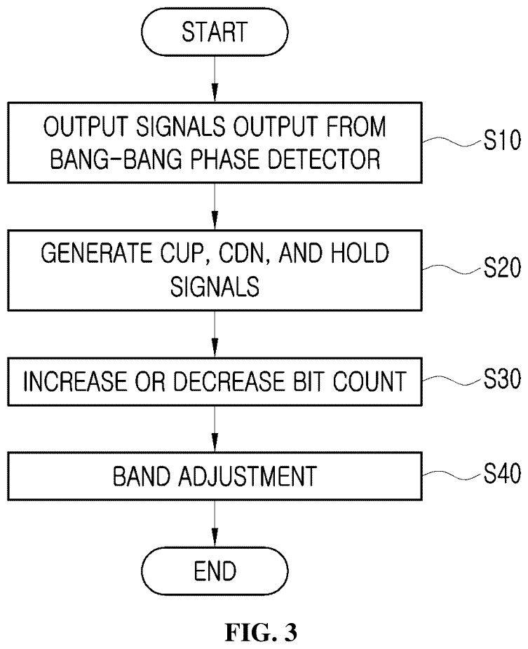

Hereinafter, referring to FIGS. 3 to 8C, a method for automatic band selection for DisplayPort according to an embodiment of the present disclosure is described.

FIG. 3 is an operational flowchart illustrating the method for automatic band selection for DisplayPort according to an embodiment of the present disclosure. With reference to FIG. 3, detailed operations in the present disclosure are described.

According to an embodiment of the present disclosure, an operation is performed on output signals of the bang-bang phase detector (BBPFD) by respective logic gates and the output signals on which the operation has been performed are output (S10).

In detail, among output signals of the bang-bang phase detector, a Fast_norm signal used to generate an output and a Slow signal output in correspondence with a relationship between a clock and a data rate are used to perform AND, XOR, and NOR logical operations, and signals obtained by performing the AND, XOR, and NOR logical operations are output.

Additionally, the bang-bang phase detector may output a signal by dividing a frequency-divided signal into four sections according to the data rate.

Then, the signals output in operation S10 are input to a latch, and CUP, CDN, and HOLD signals are generated according to a predefined condition (S20).

At this time, the latch operates to be synchronized by an edge detector with a clock that operates with a period of 64 divisions.

In addition, when the Fast_norm signal is identical to the Slow signal, a CUP or CDN signal for increasing or decreasing a bit count is generated, and when the Fast_norm signal is different from the Slow signal, a HOLD signal for maintaining the bit count is generated.

The Fast norm signal and the Slow signal have different possibilities of occurrence in four sections depending on a relationship between a data rate and a clock frequency. Among the four sections, a section (1, 1) in which both the Fast_norm signal and the Slow signal occur corresponds to a case in which a data rate is faster than a clock frequency (the clock frequency is 0.875 times or less). Thus, a signal for raising a band in which a clock is generated needs to be generated. Accordingly, a CDN signal, i.e., a signal for raising the band is generated.

In addition, sections (0, 1) and (1, 0) in which the Fast_norm signal and the Slow signal are different correspond to a case in which a difference between a data rate and a clock frequency is not great (the clock frequency is equal to or greater than 0.875 times and equal to or less than 1.75 times). Thus, a band should not be changed. Accordingly, a signal for maintaining a current band, i.e., a HOLD signal is generated.

Last, a section (0, 0) in which neither the Fast_norm signal nor the Slow signal occurs corresponds to a case when a data rate is slower than a clock frequency (the clock frequency is 1.75 times or more). Thus, a signal for lowering a band in which a clock is generated needs to be generated. Accordingly, a signal for lowering the band, i.e., a CUP signal is generated.

At this time, ranges of the CUP, CDN, and HOLD signals are defined as shown in (b) in Table 1 below.

In Table 1, (a) shows possibilities of occurrence of the Fast_norm signal and the Slow signal according to a section of a frequency range, and (b) shows a table showing definition of a state according to each possibility section.

TABLE 1

| | Possibility of BBPFD output | | | Counter |
|---|---|---|---|---|
| Frequency range | FAST_norm | SLOW | State | (Band) |
| 1.75f_{DATA} < f_{CLK} | 0 | 0 | CUP = 1 | +1 bit |
| 0.875f_{DATA} < f_{CLK} < f_{DATA} | 0 | 1 | Hold | Hold |
| f_{DATA} < f_{CLK} < 1.75f_{DATA} | 1 | 0 | Hold | |
| f_{CLK} < 0.875f_{DATA} | 1 | 1 | CDN = 1 | −1 bit |

0: not possible 1: possible

| | |
|---|---|
| (a) | (b) |

In Table 1, 1 and 0 have a probabilistic meaning. Here, 1 indicates that a signal may occur, but does not mean that the signal definitely occurs. Thus, this includes both a case in which the signal occurs and a case in which the signal does not occur. 0 means that a signal never occurs. Therefore, a determination or decision process for fixing a possibility to a certain value, and the decision is made during a period of a 64-divided clock.

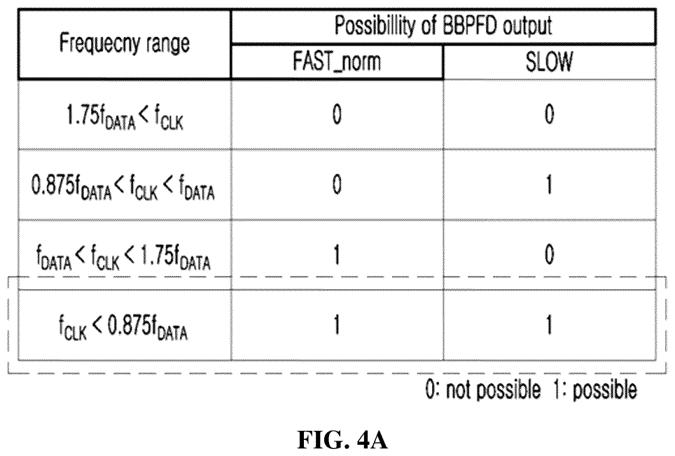

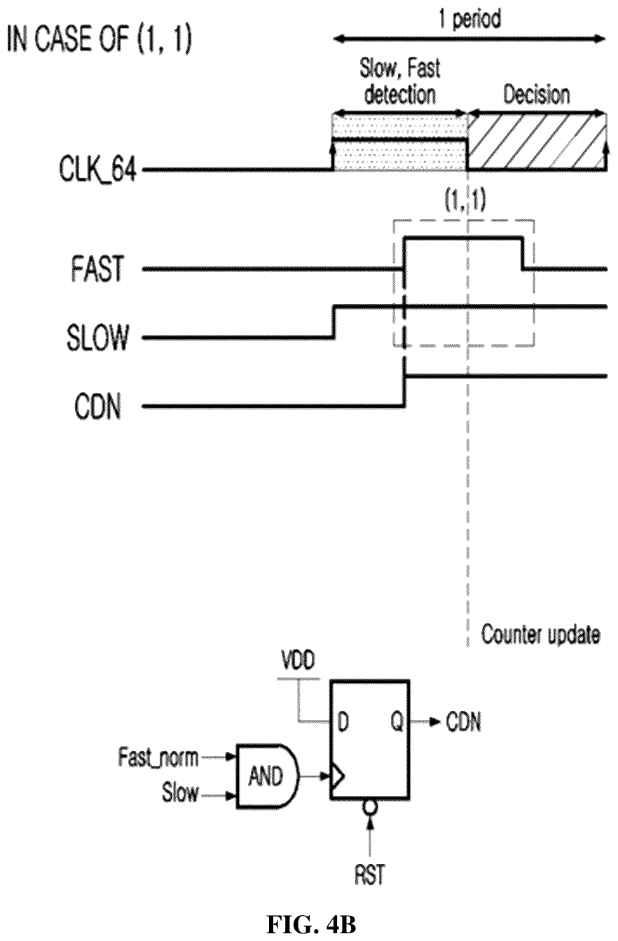

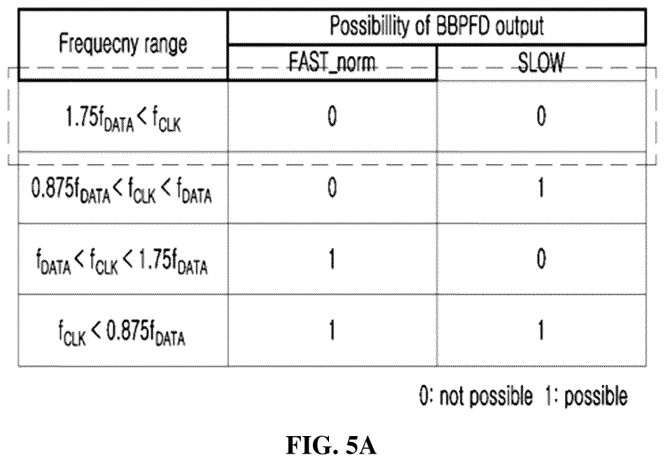

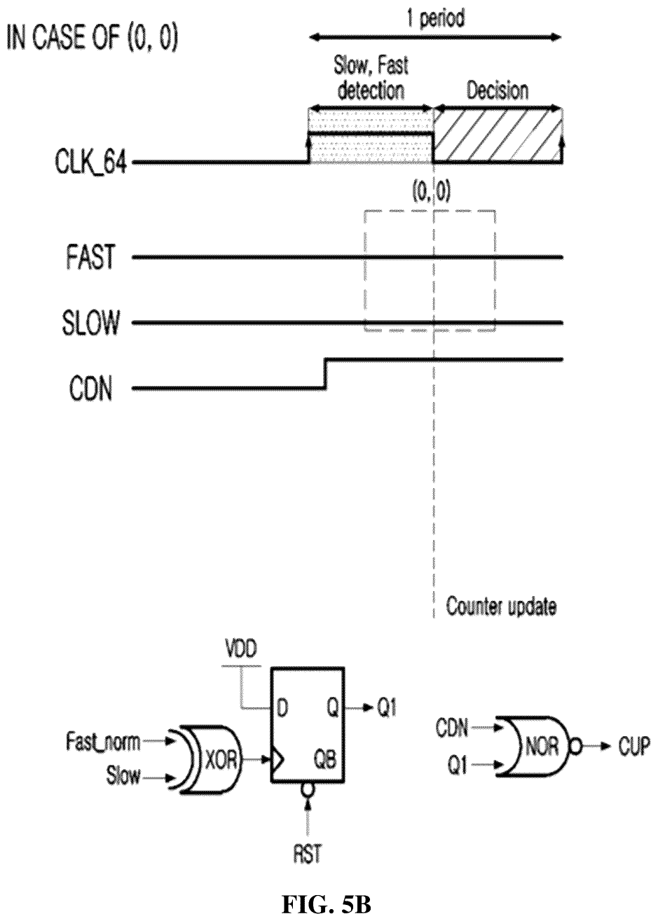

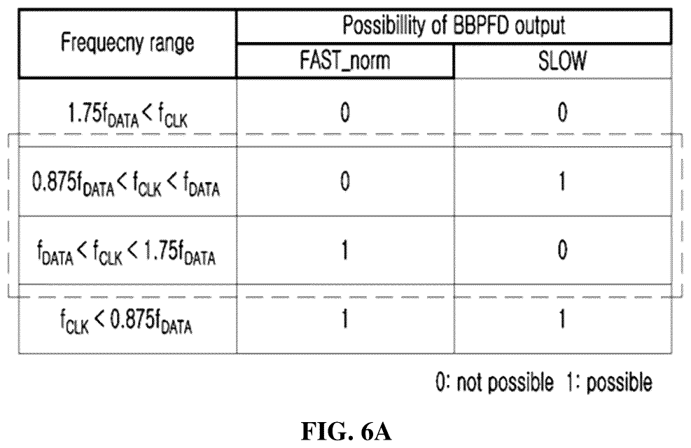

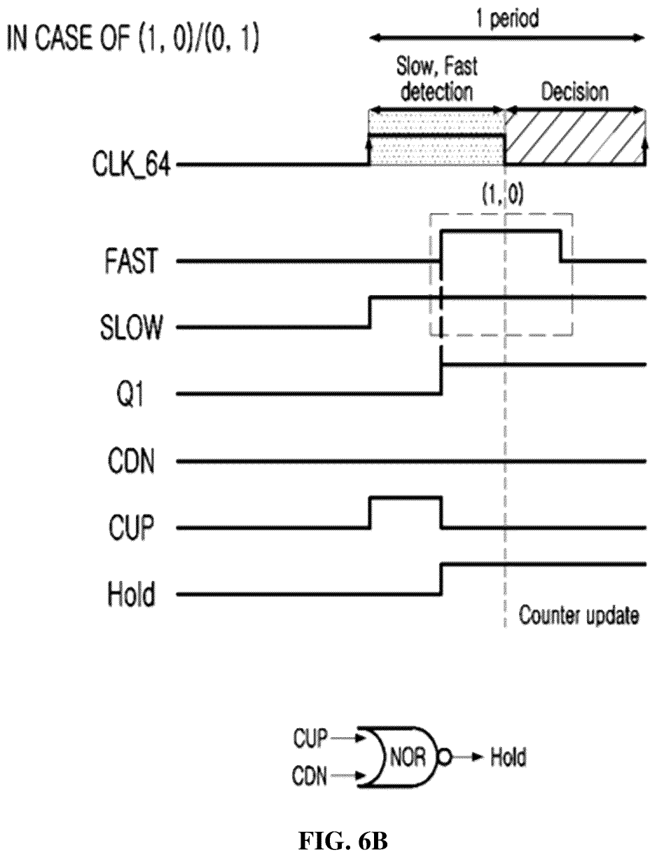

FIGS. 4A-4B are diagrams illustrating a process of generating a CDN signal according to an embodiment of the present disclosure. FIGS. 5A-5B are diagrams illustrating a process of generating a CUP signal according to an embodiment of the present disclosure. FIGS. 6A-6B are diagrams illustrating a process of generating a HOLD signal according to an embodiment of the present disclosure.

FIGS. 4A to FIG. 6A show possibilities of occurrence of the Fast_norm signal and the Slow signal according to a frequency range section. FIGS. 4A to FIG. 6B show respective output operation diagrams and respective output logic circuits.

The section (1, 1) in which both the Fast_norm signal and the Slow signal occur corresponds to a case in which a clock frequency is 0.875 times slower than a data rate. Thus, when the section (1, 1) occurs even once during one period of a 64-divided clock, a “CDN” signal is output. This is implemented using an AND gate logic circuit and a D latch as in shown in FIG. 4B, and when the Slow signal and the Fast_norm signal occur simultaneously as shown in the output operation diagram, a clock of the D latch becomes 1 and output CDN=1 occurs. That is, the output CDN indicates that a relationship between data and a clock is Fclk<0.875Fd. In addition, the latch is reset at each rising edge of the 64-divided clock to repeat a new decision in each of 64 divisions.

In addition, in the section (0, 1) or (1, 0) in which only one of the Fast_norm signal and the Slow signal occurs, a clock frequency is greater than or equal to 0.875 times and less than or equal to 1.75 times. Thus, when the CDN and CUP signals do not occur and only one of the Fast_norm signal and the Slow signal occurs during one period of the 64-divided clock, a “HOLD” signal is output. This is implemented using a NOR gate logic circuit as shown in FIG. 5B, and when only one of the Fast_norm signal and the Slow signal is 1, HOLD=1 occurs. That is, output HOLD may be defined as a situation in which Fd<Fclk<1.75Fd and 0.875Fd<Fc<Fd.

The section (0, 0) in which neither the Fast_norm signal nor the Slow signal occurs corresponds to a case in which a clock frequency is 1.75 times faster than a data rate. Thus, when the section (0, 0) occurs even once during one period of the 64-divided clock, the “CUP” signal is output. This is implemented using an XOR gate logic circuit and a D latch as shown in FIG. 6B, and a Q1 signal generated when either of the two signals occurs is used, and when neither the Q1 signal nor the CDN signal occurs, a CUP signal is generated. As shown in the output operation diagram, when the Slow signal and the Fast_norm signal do not occur simultaneously, a clock of the D latch becomes 0 and output CUP=1 occurs. That is, the output CDN indicates that a relationship between data and a clock is 1.75Fd<Fclk. In addition, the latch is reset at each rising edge of the 64-divided clock to repeat a new decision in each of 64 divisions.

Next, the CUP, CDN, and HOLD signals generated in operation S20 are input to an up-down counter to increase or decrease a bit count (S30).

Finally, the band is adjusted in correspondence with the increase or decrease in the bit count in operation S30 (S40).

In detail, the band is adjusted to be inversely proportionally to the bit count in operation S30. That is, when the beat count is increased, the band is lowered, and when the beat count is decreased, the band is raised.

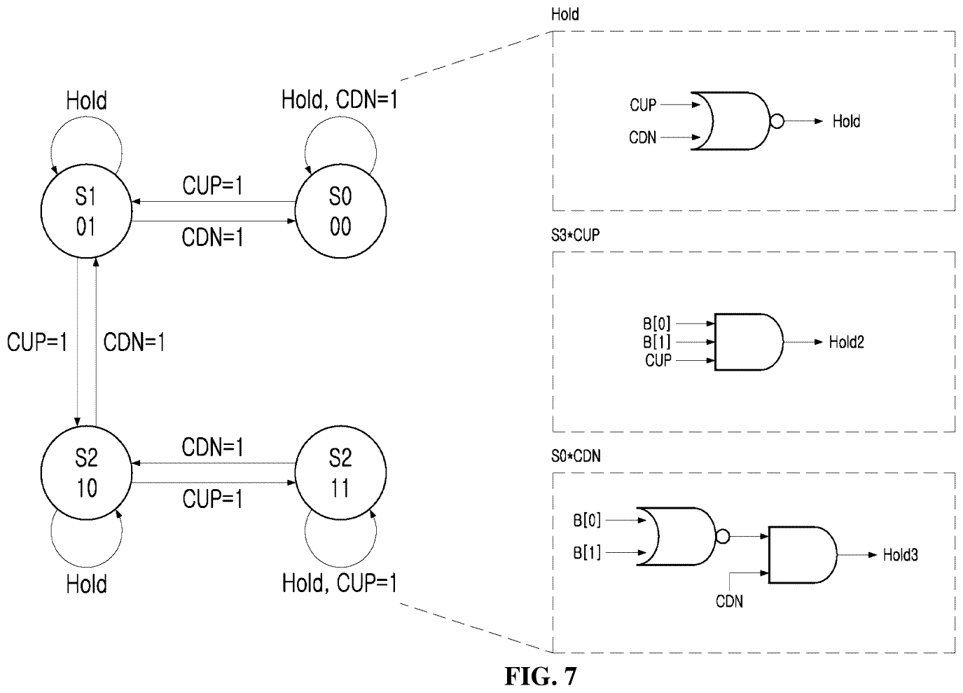

FIG. 7 shows a state diagram of a counter according to an embodiment of the present disclosure and a diagram illustrating an example of implementation of a HOLD logic.

As shown in FIG. 7, a two-bit up-down counter may be applied as an up-down counter in an embodiment of the present disclosure.

Referring to FIG. 7, an operation of the up-down counter is described. An output of the up-down counter becomes an oscillator band signal, and counter outputs A and B are initially set to 1 and 0, respectively, to start from a middle band, i.e., a band “10,” for fast frequency tracking. Likewise, an initial code of the oscillator is set as a code which is a center frequency of the band “10.” Therefore, according to a state diagram, when the CDN signal occurs, a counter output is lowered by one bit, and when the CUP signal occurs, a counter output is raised by one bit. In addition, when the Hold signal occurs, a counter input is blocked, and the counter does not operate, thus, a current state is maintained.

In FIG. 7, a case when neither a CUP signal nor a CDN signal occurs is defined as HOLD. When the CDN signal occurs when both A and B=00, since a bit cannot be further raised, a state also needs to be maintained. This case may be defined as Hold2. In addition, when the CDN signal occurs when both A and B=11, since a bit cannot be further lowered, a state also needs to be maintained. This case may be defined as Hold3. Signals of Hold, Hold2, and Hold3 may be implemented through a logic circuit shown on a right side in FIG. 7.

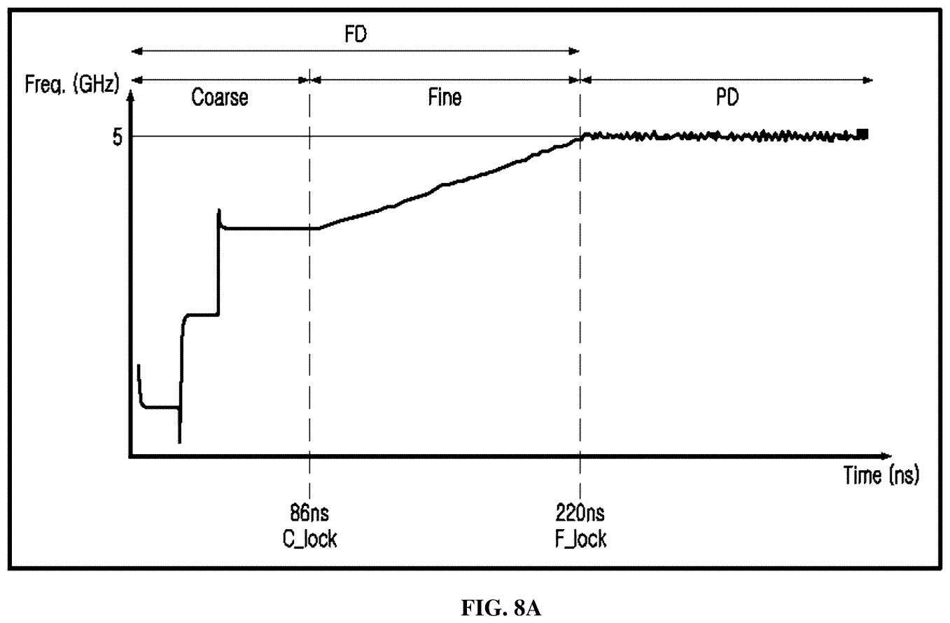

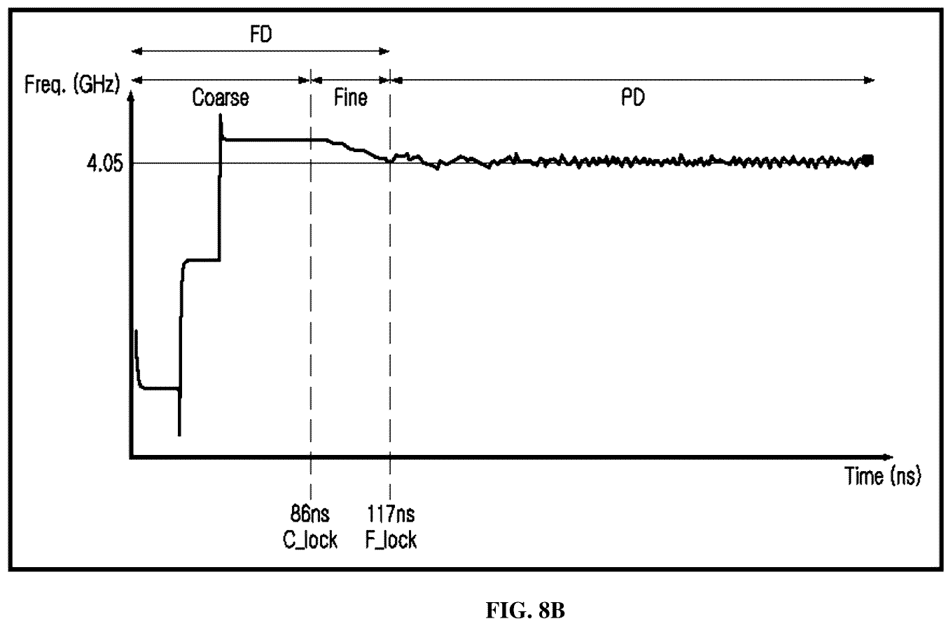

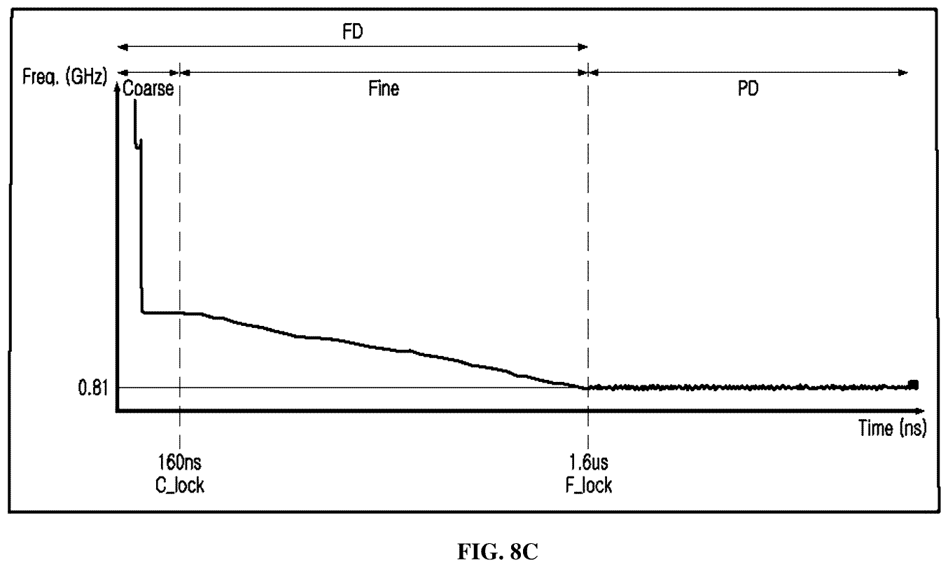

FIGS. 8A-8C are graphs showing a simulation result according to an embodiment of the present disclosure.

FIGS. 8A-8C show results of overall CDR simulation. FIG. 8A is a graph showing a change in a band at a rate of 20 Gb/s. FIG. 8B is a graph showing a change in a band at a rate of 8.1 Gb/s. FIG. 8C is a graph showing a change in a band at a rate of 1.62 Gb/s.

As shown in FIGS. 8A-8C, according to an embodiment of the present disclosure, a wide data range may be supported, and it may be checked that a portion in which a frequency is increased or decreased in a stepwise form in a Coarse stage. It may be understood that the band is adjusted by being automatically raised or lowered in this portion.

The method for automatic band selection for DisplayPort according to an embodiment of the present disclosure has been described above.

In addition, the method for automatic band selection for DisplayPort according to an embodiment of the present disclosure as described above may be provided in a form of a computer-readable medium suitable for storing a computer program instruction and data thereon.

In particular, a computer program in the present disclosure may execute operations including performing an operation on output signals of a bang-bang phase detector (BBPFD) by respective logic gates and outputting the output signals on which the operation has been performed, inputting the output signals to a latch to generate CUP, CDN, and HOLD signals according to predefined conditions, increasing or decreasing a bit count when the generated CUP, CDN and HOLD signals are input to an up-down counter, and adjusting a band in correspondence with the increase or decrease in the bit count.

According to the present disclosure as described above, performance of a CDR circuit may be enhanced by introducing a multi-band oscillator and an automatic band selection function to support a wide data range. Thus, damaged data at various frequencies may be quickly and accurately recovered, and requirements for high data rates may be stably satisfied.

In addition, a sophisticated clock and data recovery function with improved jitter performance may be provided to support next-generation standards for DisplayPort and other video interface technologies.

In addition, high performance and reliability may be provided in a field in which fast data recovery and stable clock generation and high-speed data transmission are essentially needed, i.e., in such application fields as high-definition video and graphics transmission, medical imaging and telemedicine, virtual reality and augmented reality systems.

Although the present disclosure has been described with reference to an embodiment illustrated in the drawings, this is only an example, and it will be understood by those of ordinary skill in the art that various changes in the form and details may be made therein without departing from the spirit and scope of the present disclosure.

1. An automatic band selection method performed by an apparatus for automatic band selection for DisplayPort, the apparatus having circuits comprising logic gates, a latch, an up-down counter, the automatic band selection method comprising:
performing an operation on first output signals of a bang-bang phase detector (BBPFD) by the logic gates respectively, and outputting second output signals on which the operation has been performed;
generating CUP, CDN, and HOLD signals according to a predefined condition by inputting the second output signals to the latch;
increasing or decreasing a bit count by inputting the generated CUP, CDN and HOLD signals to the up-down counter; and
adjusting a band in correspondence with the increase or decrease in the bit count.

2. The automatic band selection method of claim 1,
wherein the performing of the operation and the outputting comprise performing AND, XOR, and NOR logical operations using a Fast_norm signal used to generate an output and a Slow signal output in correspondence with a relationship between a clock and a data rate, among the first output signals of the BBPFD, and outputting signals obtained by the performing of the AND, XOR, and NOR logical operations, and
wherein the BBPFD outputs the first output signals by dividing a frequency-divided signal into four sections according to the data rate.

3. The automatic band selection method of claim 2,
wherein the generating of the CUP, CDN, and HOLD signals comprises generating the CUP or CDN signal for increasing or decreasing the bit count when the Fast_norm signal is identical to the Slow signal, and generating the HOLD signal to maintain the bit count when the Fast_norm signal is different from the Slow signal, and
wherein the latch operates to be synchronized by an edge detector with a clock that operates with a period of 64 divisions.

4. The automatic band selection method of claim 3, wherein the adjusting of the band comprises adjusting of the band to be inversely proportional to the bit count.

5. An apparatus for automatic band selection for DisplayPort, the apparatus comprising:
a signal output unit configured to output a signal obtained by performing, by a logic gate, an operation using a Fast_norm signal used to generate an output and a Slow signal output in correspondence with to a relationship between a clock and a data rate, among output signals of a bang-bang phase detector (BBPFD),
a signal generation unit configured to generate CUP, CDN, and HOLD signals according to a predefined condition when the output signal obtained by the logic gate is input to a latch; and
a band adjustment unit configured to adjust a band in correspondence with an increase or decrease in a bit count when the bit count is increased or decreased according to input of the generated CUP, CDN, and HOLD signals to an up-down counter.
